(19) United States
(12) Patent Application Publication
(10) Pub. No.: US 2014/0197018 A1
(43) Pub. Date: Jul. 17, 2014

(54) TOUCH PANEL

(71) Applicant: HENGHAO TECHNOLOGY CO. LTD, Taoyuan County (TW)

(72) Inventor: CHI-AN CHEN, Taipei City (TW)

(73) Assignee: HENGHAO TECHNOLOGY CO. LTD, Taoyuan County (TW)

(21) Appl. No.: 13/746,261

(22) Filed: Jan. 21, 2013

(30) Foreign Application Priority Data
Jan. 11, 2013 (TW) 102101208

(51) Int. Cl. H03K 17/96

(52) U.S. Cl. CPC H03K 17/9622
USPC 200/600

(57) ABSTRACT

A touch panel includes a first electrode layer and a second electrode layer disposed above a transparent substrate. At least one transparent insulating layer is disposed between the first electrode layer and the second electrode layer. The electrode pattern of the first electrode layer has more than four sides, and the electrode pattern of the second electrode layer substantially complements the electrode pattern of the first electrode layer.

### CROSS-REFERENCE TO RELATED APPLICATIONS

The entire contents of Taiwan Patent Application No. 102101208, filed on Jan. 11, 2013, from which this application claims priority, are incorporated herein by reference.

### BACKGROUND OF THE INVENTION

1. FIELD OF THE INVENTION

The present invention generally relates to a touch panel, and more particularly to a touch panel with a specific electrode pattern.

2. DESCRIPTION OF RELATED ART

A touch screen is an input/output device that adopts sensing technology and display technology, and has been widely employed in electronic devices such as portable or hand-held electronic devices.

A capacitor-based touch panel is a commonly used touch panel that utilizes capacitive coupling effect to detect touch position. Specifically, capacitance corresponding to the touch position changes and is thus detected, when a finger touches a surface of the touch panel.

FIG. 1. shows a top view of a conventional touch panel 100, which primarily includes an X-axis electrode layer 110 and a Y-axis electrode layer 120. As shown in FIG. 1, the electrodes of the X-axis electrode layer 110 and the Y-axis electrode layer 120 have a rhombus shape. Large-size widescreen touch panels with the rhombus-shaped electrodes suffer high resistivity. Moreover, trace phenomenon may occur to impact visual appearance when users look at the touch panel 100. Further, the conventional touch panel 100 lacks sufficient amount of touch sensing for the reason that the amount of touch sensing is provided only by electrode boundary regions 130 between the X-axis electrode layer 110 and the Y-axis electrode layer 120.

A need has thus arisen, to propose a novel touch panel to overcome deficiencies of the conventional touch panels.

### SUMMARY OF THE INVENTION

In view of the foregoing, it is an object of the embodiment of the present invention to provide a touch panel to improve trace phenomenon, resistivity of large-size widescreen touch panels or an amount of touch sensing.

According to one embodiment, a touch panel includes a transparent substrate, a first electrode layer, at least one transparent insulating layer and a second electrode layer. The first electrode layer is disposed above the transparent substrate. The first electrode layer includes a plurality of first electrode lines that are disposed in parallel, each of the first electrode lines including a plurality of first electrodes that are connected in series via first interconnect elements. The at least one transparent insulating is disposed above the first electrode layer. The second electrode layer is disposed above the at least one transparent insulating layer. The second electrode layer includes a plurality of second. electrode lines that are disposed in parallel, each of the second electrode lines including a plurality of second electrodes that are connected in series via second interconnect elements. The first electrodes have a shape having more than four sides, and the second electrodes have a shape that substantially complements the shape of the first electrodes.

### BRIEF DESCRIPTION OF THE DRAWINGS

FIG. 1 shows a top view of a conventional touch panel;

FIG. 2 shows a top view of a touch. panel according to one embodiment of the present invention; and

FIG. 3 shows a stacking structure of the touch panel of FIG. 2.

### DETAILED DESCRIPTION OF THE INVENTION

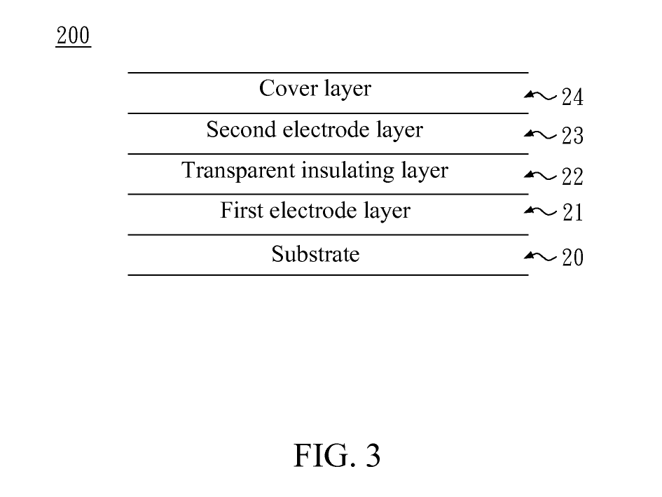

FIG. 2 shows a top view of a touch panel 200 according to one embodiment of the present invention, and FIG. 3 shows a stacking structure of the touch panel 200 of FIG. 2. The embodiment may be preferably, but not necessarily, adapted to a widescreen touch panel, for example, with an aspect ratio of 16:9 (i.e., with a width of 16 units and a height of 9 units).

As shown in FIG. 2/3, the touch panel 200 includes a first electrode layer 21 formed on a transparent substrate 20. The transparent substrate 20 may include insulating material such as glass, Polycarbonate (PC), Polyethylene terephthalate (PET), Polyethylen (PE), Poly vinyl chloride (PVC), Poly propylene (PP), Poly styrene (PS), Polymethyl methacrylate (PMMA) or Cyclic olefin copolymer (COC).

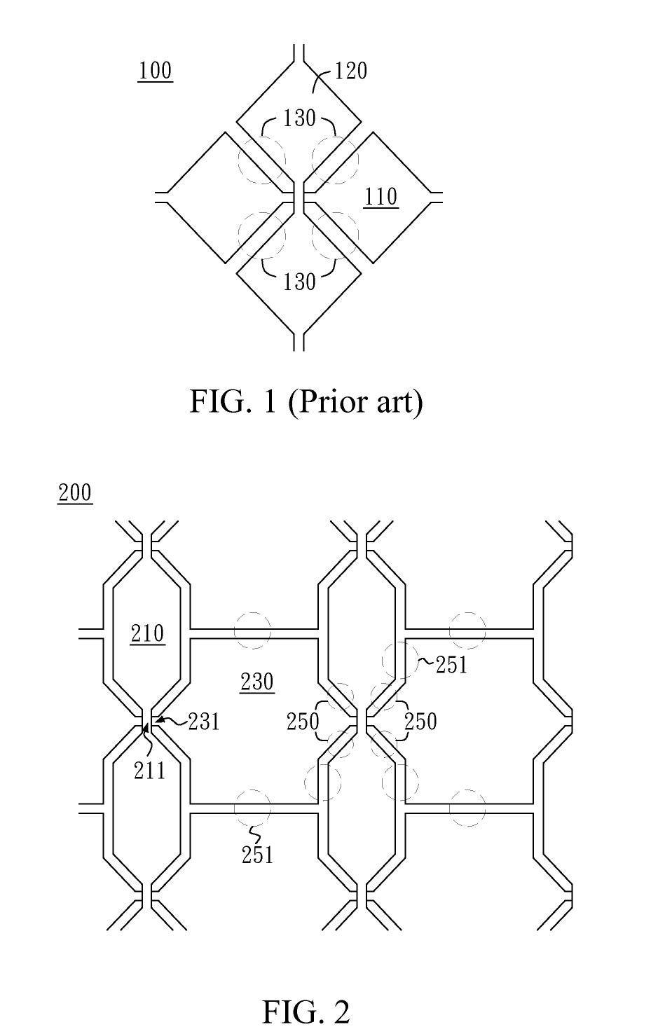

The first electrode layer 21 includes plural first electrode lines disposed in parallel, for example, as transmit electrodes (Tx). Each first electrode line, disposed along a first direction (e.g., height of the touch panel 200), is comprised of plural first electrodes 210, which are connected in series via first interconnect elements 211. In the embodiment, the first electrodes 210 have a six-sided (or hexagon) shape, instead of the rhombus shape in the conventional touch panel (e.g., shown in FIG. 1).

The touch panel 200 also includes a second electrode layer 23 formed above the first electrode layer 21. At least one transparent insulating layer 22, disposed between the second electrode layer 23 and the first electrode layer 21, is used to electrically insulate the second electrode layer 23 from the first electrode layer 21 and to bond the second electrode layer 23 with the first electrode layer 21.

The second electrode layer 23 includes plural second electrode lines disposed in parallel, for example, as receive electrodes (Rx). Each second electrode line, disposed along a second direction (e.g., width of the touch panel 200), is comprised of plural second electrodes 230, which are connected in series via second interconnect elements 231. The first direction and the second direction mentioned above may, but not necessarily, be substantially perpendicular with each other. In the embodiment, the second electrodes 230 (having a ten-sided shape as exemplified in FIG. 2) have a shape that substantially complements the six-sided shape of the first electrodes 210, instead of the rhombus shape in the conventional touch panel (e.g., shown in FIG. 1). The complementary first electrodes 210 and the second electrodes 230 substantially cover a top active surface of the touch panel 200. In one embodiment, a gap between neighboring first electrode 210 and second electrode 230 is less than 30 micrometers.

As the first electrodes 210 and the second electrodes 230 make a good combination with small gaps, trace phenomenon may thus be greatly improved. The resistivity of a large-size widescreen touch panel adopting the electrodes discussed above may be substantially reduced. Moreover, the amount of touch sensing may be greatly enhanced by utilizing the electrodes discussed above due to increased neighboring regions 251 between the first electrodes 210 and the second electrodes 230, therefore enhancing touch performance. Specifically speaking, as exemplified in FIG. 2, the amount of touch sensing is provided not only by electrode boundary regions 250 between the first electrodes 210 and the second electrodes 230, but also by the neighboring regions 251 between the first electrodes 210 and the second electrodes 230.

In one embodiment, the first electrode layer 21 and the second electrode layer 23 may include a light-transmissive structure made of a non-transparent material. The non-transparent material may include metal nanowires (e.g., silver nanowires or copper nanowires) or metal nanonets (e.g., silver nanonets or copper nanonets). The metal nanowires or nanonmeters have a diameter in a nanometer order (i.e., a few nanometers to hundreds nanometers), and may be fixed via a plastic material (e.g., resin). Due to fineness of the metal nanowires/nanonets unobservable to human eyes, the first electrode layer 21 and the second electrode layer 23 made of the metal nanowires/nanonets thus have high light-transmittance. In another embodiment, the first electrode layer 21 and the second electrode layer 23 may further include a photosensitive material (e.g., acrylic), through which electrodes 210/230 with a required pattern may be formed via an exposure development process.

In another embodiment, one of the first electrodes 210 and the second electrodes 230 may include a light-transmissive structure made of a transparent material. The transparent material may include indium tin oxide (ITO), indium zinc oxide (IZO), Al-doped. ZnO (AZO) or antimony tin oxide (ATO).

More than one transparent insulating layer 22 may be utilized. The transparent insulating layer 22 may include an anti-split film (ASF), an optical clear adhesive (OCA) or other insulating layers with specific functions. Moreover, the first electrode layer 21 or the second electrode layer 23 including the non-transparent material (e.g., metal nanowires) may further include an insulating layer disposed on its top surface or bottom surface when required.

The touch panel 200 may further include a cover layer 24 formed above the second electrode layer 23. The cover layer 24 may include insulating material with high transmittance such as glass, Polycarbonate (PC), Polyethylene terephthalate (PET), Polymethyl methacrylate (PMMA) or Cyclic olefin copolymer (COC).

Although specific embodiments have been illustrated and described, it will be appreciated by those skilled in the art that various modifications may be made without departing from the scope of the present invention, which is intended to be limited solely by the appended claims.

What is claimed is:

1. A touch panel, comprising:
a transparent substrate;
a first electrode layer disposed above the transparent substrate, the first electrode layer including a plurality of first electrode lines that are disposed in parallel, each of the first electrode lines including a plurality of first electrodes that are connected in series via first interconnect elements;
at least one transparent insulating layer disposed above the first electrode layer; and
a second electrode layer disposed above the at least one transparent insulating layer, the second electrode layer including a plurality of second electrode lines that are disposed in parallel, each of the second electrode lines including a plurality of second electrodes that are connected in series via second interconnect elements;
wherein the first electrodes have a shape having more than four sides, and the second electrodes have a shape that substantially complements the shape of the first electrodes.

2. The touch panel of claim 1, wherein the transparent substrate comprises glass, Polycarbonate (PC), Polyethylene terephthalate (PET), Polyethylen (PE), Poly vinyl chloride (PVC), Poly propylene (PP), Poly styrene (PS), Polymethyl methacrylate (PMMA) or Cyclic olefin copolymer (COC).

3. The touch panel of claim 1, wherein the first electrodes have a six-sided shape.

4. The touch panel of claim 1, wherein a gap between neighboring first electrode and second electrode is less than 30 micrometers.

5. The touch panel of claim 1, wherein the first electrode layer or the second electrode layer comprises a light-transmissive structure made of a non-transparent material.

6. The touch panel of claim 5, wherein the non-transparent material comprises metal nanowires or metal nanonets.

7. The touch panel of claim 5, further comprising an insulating layer disposed on a surface of the non-transparent material.

8. The touch panel of claim 5, wherein one of the first electrode layer and the second electrode layer comprises a light-transmissive structure made of a transparent material.

9. The touch panel of claim 8, wherein the transparent material comprises indium tin oxide (ITO), indium zinc oxide (IZO), Al-doped ZnO (AZO) or antimony tin oxide (ATO).

10. The touch panel of claim 1, wherein the transparent insulating layer comprises an anti-split, film (ASF).

11. The touch panel of claim 1, further comprising a cover layer disposed above the second electrode layer.
